(19) United States
(12) Patent Application Publication
(10) Pub. No.: US 2013/0142979 A1
(43) Pub. Date: Jun. 6, 2013

(54) Thermoformed IC Trays Of Poly(Phenylene Ether) Compositions

(71) Applicants: Kurt S. Edwards, Chino Hills, CA (US); Chuan Tat Choo, Kuala Lumpur (MY); Qiwei Lu, Seven Hills, OH (US); Kenneth Sienkowski, Cumming, GA (US); Kong Chin Chew, Selangor (MY); Vanessa Mirabile, Chicago, IL (US)

(72) Inventors: Kurt S. Edwards, Chino Hills, CA (US); Chuan Tat Choo, Kuala Lumpur (MY); Qiwei Lu, Seven Hills, OH (US); Kenneth Sienkowski, Cumming, GA (US); Kong Chin Chew, Selangor (MY); Vanessa Mirabile, Chicago, IL (US)

(73) Assignee: LUBRIZOL ADVANCED MATERIALS, INC., Cleveland, OH (US)

(21) Appl. No.: 13/805,035

(22) PCT Filed: Jun. 27, 2011
(86) PCT No.: PCT/US2011/041950

§ 371 Date: Feb. 25, 2013

Related U.S. Application Data
(60) Provisional application No. 61/360,521, filed on Jul. 1, 2010.

(51) Int. Cl. H01L 21/673

(52) U.S. Cl. CPC H01L 21/67336
USPC 428/36.92

(57) ABSTRACT

The present invention relates to a component carrier tray, and more particularly, a thermoformed carrier tray for integrated circuit (IC) components such as IC chips. The trays of the present invention have the benefit of being suitable for all parts of the IC component manufacturing process, including being suitable for the steps of transporting, sorting, storing, baking, etc. Thus the trays of the present invention reduce the need for transferring IC components from one tray to another and as a result reduce manufacturing cost and risk of part damage. The trays of the present invention are particularly suitable for mid-temperature applications.

### FIELD OF THE INVENTION

The present invention relates to a component carrier tray, and more particularly, a carrier tray for integrated circuit (IC) components such as IC chips. The trays of the present invention have the benefit of being suitable for multiple parts of the IC component manufacturing process, including being suitable for the steps of transporting, sorting, storing, baking, etc. Thus, the trays of the present invention reduce the need for transferring IC components from one tray to another and as a result reduce manufacturing cost and risk of part damage. The trays of the present invention are particularly suitable for mid-temperature applications, for example, from 125 to 150 degrees C.

### BACKGROUND OF THE INVENTION

Prefabricated components and chips lie at the heart of most analog and digital circuits. As these circuits become more prevalent and more complex, it has become increasingly important to those who manufacture and sell the component parts, as well as to those who purchase components and implement circuits using them, that these often delicate or sensitive components can be inspected efficiently and effectively, shipped securely, and handled easily during formation and installation. Similar demands exist with respect to other electrical and mechanical components.

Component manufacturers traditionally handle their parts during production in various forms of transport packaging, in the past a popular system included waffle trays. In waffle trays, and similar systems, each tray is formed with a series of depressions or pockets formed in a grid pattern. A component part is inserted into a pocket and transported therein. This system provides an efficient arrangement in which the components can be stored or manipulated by an automated assembly process.

In order to facilitate the handling of these carrier trays, the Joint Electronic Device Engineering Council (JEDEC) promulgated standards for size and shape. JEDEC standards dictate the form of such exterior features as end tabs for machine manipulation and complementary top and bottom features for stacking.

In addition to facilitating handling of the carrier, it is important in automated production lines to ensure that the components remain oriented properly within the carrier. This permits the machinery to determine the location and orientation of particular components with sufficient accuracy. In addition, the leads of the components are often quite delicate and therefore susceptible to damage during formation, shipping and storage. Accordingly, it is beneficial to form pockets with interior features, well known in the art, designed to orient and protect the component from being bounced against the interior surfaces of the pocket.

In order to form trays with exterior features meeting JEDEC standards and interior pocket features that will adequately accommodate the components therein, trays are usually injection molded of a thermoplastic resin that is substantially amorphous (rather than crystalline or semi-crystalline) such as acrylonitrile butadiene styrene (ABS). Special additives are often added to try and improve tray performance, including for heat resistance. However, it is our experience that these materials, even when performance additives are used, generally do not fare well when exposed to temperatures at or above approximately 125 degrees C. It is becoming common for manufacturers to subject the components to those temperatures and even higher temperatures, with common mid-temperature processing operating at about 125 to 150 degrees C., and some processes going to even higher temperatures. These “baking” steps, completed at elevated temperatures are generally used to remove potentially-damaging trapped moisture from components prior to the installation processes. Also, while injection molded trays are available that can withstand these baking steps, the materials used to make the trays typically contain substantial amounts of reinforcing fillers, which lead to higher material density, and so higher weights of the trays, leading to higher shipping costs, particularly air freight costs, when such trays are used across multiple steps.

When trays used in one part of the process cannot withstand the required baking temperatures, the components must be removed from said trays and transferred to more heat resistance trays before the components can be subjected to such processes. Furthermore, once the baking step is complete, it is not uncommon for the components to be transferred again from the heat resistant tray to a tray more compatible with the rest of the manufacturing process. Still further transfers of components from one tray type to another may be required, for example, when moving components from light weight trays with good component stabilization, such as those often used for shipping components, to trays with frames and supports designed for a particular production line. Each transfer of components from one tray to another requires specialized and expensive equipment that can safely and efficiently transfer components from one try to another. Furthermore, each transfer poses a risk of damaging the component being moved. In addition, each type of tray required in the manufacturing process represents additional cost that adds to the cost of the component being made.

It would greatly facilitate the handling of the components and the cost of their manufacture if the trays in which they are handled could be used in multiple steps of the manufacturing process, thus eliminating the need for one or more components transfers, and resulting in reduced costs and reduced risk of damage in the overall process. In other words, there is need for JEDEC compatible IC component trays that: (i) can withstand the elevated temperatures encountered in such component manufacturing (such as the temperatures seen in mid-temperature baking steps), (ii) have a specific gravity low enough that their weight is attractive from a shipping and handling perspective, (iii) have sufficient strength, impact and related physical properties to provide adequate support to the components over the course of the manufacturing process, (iv) have adequate electrostatic and conductivity properties to make them appropriate for use with ESD sensitive IC components, or (v) combinations thereof. Such trays could be used in multiple steps of the supply chain and manufacturing process for IC components, and even across all of the steps involved, thus greatly reducing complexity, cost, and risk of damage in the overall process.

### SUMMARY OF THE INVENTION

The present invention provides a thermoformed tray for transporting and processing integrated circuit (IC) chips comprising at least one pocket designed to receive said IC chips, wherein said tray comprises a thermoplastic polymer compound comprising: (i) a poly(phenylene ether) (PPE) polymer; (ii) a conductive filler; (iii) an impact modifier; and (iv) optionally one or more additional additives.

The invention provides for said tray being made from a poly(phenylene ether) homopolymer, a poly(phenylene ether) copolymer, a poly(phenylene ether) blend, or combinations thereof. Suitable blends include blends of poly(phenylene ether) polymer with polystyrene, high impact polystyrene, styrenic block copolymers, or combinations thereof. In some embodiments, the poly(phenylene ether) is poly(2,6-dimethylphenylene oxide).

The invention further provides for trays made from a polymer that has a heat distortion temperature of no lower than 130 degrees C. as measured under 66 psi (0.46 MPa) according to ASTM D-648, has a surface resistance of less than 1E8 ohm as measured according to ESD S11.11, has a flexural modulus of at least 250 kpsi (1723 MPa) as measured according to ASTM D-790, has a specific gravity of less than 1.18 g/cc as measured according to ASTM D-792, or any combination thereof.

The invention further provides for any of the trays described herein where the tray is produced by the thermoforming of a sheet of said polymer compound. The invention further provides JEDEC-compatible trays made from any of the materials described herein.

### DETAILED DESCRIPTION OF THE INVENTION

Various features and embodiments of the invention will be described below by way of non-limiting illustration.

### The Trays

The present invention provides trays for integrated circuit (IC) components and similar items. In some embodiments, the trays conform to JEDEC standards which set the tray outline, storage pocket locations, outer rail height and stacking configuration of the trays.

In some embodiments, the trays are stackable when empty. In some embodiments, the trays may be used for multiple IC chips, components and/or assemblies. In some embodiments, the trays are suitable for use with thin small outline plastic packages (TSOPs), side small outline plastic packages (SSOPs), pin grid arrays (PGAs), ball grid arrays (BGAs), or any combination thereof.

The trays of the present invention are thermoformed. The trays may be formed by drape or vacuum thermoforming. In some embodiments, the trays are formed from a sheet of polymer that is 0.020 to 0.060, 0.030 to 0.050 or even 0.035 to 0.045 inches (0.51 to 1.52, 0.76 to 1.27, or even 0.89 to 1.14 mm) thick and is a length and width that is each independently 12 to 21, 14 to 19, 15 to 18, or even 16 to 17 inches (30.5 to 53.3, 35.6 to 48.3, 38.1 to 45.7, or even 40.6 to 43.2 cm). In some embodiments, the trays of the present invention are not injection molded. Injection molding is a fundamentally different process and technique than thermoforming, and compositions suitable for use in one of these processes are often not suitable for use in the other.

The trays of the present invention are made from a thermoplastic polymer compound which includes a PPE polymer component, a conductive filler component, an impact modifier component, and optionally, an additional additive component. The PPE polymer component may be present in the thermoplastic polymer compound from 50 to 99 percent by weight, or from 50, 60, 70 or even 80 up to 99, 95, 90 or even 85 percent by weight. The conductive filler component may be present from 1 to 25 percent by weight, or from 1, 5, 10 or even 15 up to 30, 25, 20, or even 18 percent by weight. The impact modifier component may be present from 1 to 30 percent by weight, or from 1, 5 or even 9 up to 30, 25, 20, 15 or even 11 percent by weight. The optional additional additive component may be present from 0 or 0.01 to 20 percent by weight, or from 0, 0.01, 0.5 or even 1 up to 20, 10, 5, 4 or even 2 percent by weight, wherein these percent by weight values and ranges may be applied to each individual additional additive or to the entire optional additional additive component. The weight percent values and ranges provided for each of the component above are in regards to the overall thermoplastic polymer compound.

In some embodiments, the compositions that make up the trays can be defined by the weight ratio of the components relative to one another. For examples, the polymer component, impact modifier and conductive filler component may be present within weight ratios of about 3-10:0.5-1.5:1-2 respectively. The weight ratio of the polymer component to the impact modifier may be from 1 to 10:1 or from 2 to 7:1 or even from 3 to 5:1. The weight ratio of the conductive filler to the impact modifier may be from 0.5 to 2:1 or from 0.75 to 1.25:1 or even from 0.9 to 1.1 to 1.

In some embodiments, the trays of the present invention are made from a thermoplastic polymer compound that has a heat distortion temperature of no lower than 130 degrees C. as measured under 66 psi (0.46 MPa) according to ASTM D-648. In some embodiments, the heat distortion temperature of the polymer compound, and so of the trays made from the polymer compound, as measured by ASTM D-648 is no lower than 120, 125, 130, 140, 150, 180, or even 200 degrees C. In some embodiments, the trays of the invention can withstand baking temperatures of at least 120, 125, 130,140, or even 150 degrees C. without failing (tray distortion).

In some embodiments, the trays of the present invention are made from a thermoplastic polymer compound that has a surface resistance of less than 1E8 ohms as measured according to ESD S11.11. In some embodiments, the surface resistance of the polymer compound, and so of the trays made from the polymer compound, as measured by ESD S11.11 is no more than 1E8, 1E7, 1E6, or even 1E5 ohms. Measurements made according to ESD S11.11 are completed at 12% relative humidity unless otherwise noted. Surface resistance may also be measured according to ASTM D-257. Measurements made according to ASTM D-257 are completed at 50% relative humidity unless otherwise noted.

In some embodiments, the trays of the present invention are made from a thermoplastic polymer compound that has a flexural modulus of at least 250 kpsi (1.7 GPa) as measured according to ASTM D-790. In some embodiments, the flexural modulus of the polymer compound, and so of the trays made from the polymer compound, as measured by ASTM D-790 is at least 250, 300 or even 350 kpsi (1.7, 2.1 or even 2.4 GPa) as measured by ASTM D-790.

In some embodiments, the trays of the present invention are made from a thermoplastic polymer compound that has a specific gravity of less than 1.18 g/cc as measured according to ASTM D-792. In some embodiments, the specific gravity of the polymer compound, and so of the trays made from the polymer compound, as measured by ASTM D-792 is no more than 1.18, 1.16, 1.14 or even 1.12 g/cc.

The polymer compounds described herein may posses any combination of the characteristics described above, and in some embodiments possess all of the described characteristics.

### The PPE Polymer Compositions

The trays of the present invention are made from a poly(phenylene ether) (PPE) polymer. The PPE polymers suitable for use in the present invention include polymers comprising a plurality of structural units having the formula:

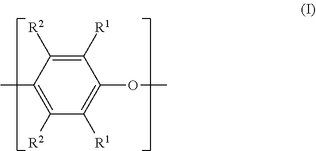

In the formula above, in each of said units independently, each R¹ is independently halogen, primary or secondary lower alkyl (i.e., alkyl containing up to 7 carbon atoms), phenyl, haloalkyl, aminoalkyl, hydrocarbonoxy, or halohydrocarbonoxy wherein at least two carbon atoms separate the halogen and oxygen atoms; and each R² is independently hydrogen, halogen, primary or secondary lower alkyl, phenyl, haloalkyl, hydrocarbonoxy or halohydrocarbonoxy as defined for R¹. Examples of suitable primary lower alkyl groups are methyl, ethyl, n-propyl, n-butyl, isobutyl, n-amyl, isoamyl, 2-methylbutyl, n-hexyl, 2,3-dimethylbutyl, 2-, 3- or 4-methylpentyl and the corresponding heptyl groups. Examples of secondary lower alkyl groups are isopropyl, sec-butyl and 3-pentyl. In some embodiments, any alkyl radicals are straight chain rather than branched. In some embodiments, each R¹ is alkyl or phenyl, for example, a C₁₋₄ alkyl, and each R² is hydrogen. In some embodiments, each R¹ is a methyl group and each R² is hydrogen.

In some embodiments, the PPE polymers suitable for the invention may be described as thermoplastic, linear, non-crystalline polyethers. In some embodiments, the PPE polymers are derived via a condensation reaction of 2,6-dimethylphenol in the presence of a copper-amine-complex catalyst. PPE polymers are also sometimes referred to as poly(phenylene oxide) (PPO) polymers.

Both homopolymer and copolymer polyphenylene ethers are within the purview of the process of the present invention. Suitable homopolymers are those containing, for example, 2,6-dimethyl-1,4-phenylene ether units. Suitable copolymers include random copolymers containing such units in combination with, for example, 2,3,6-trimethyl-1,4-phenylene ether units. Many suitable random copolymers, as well as homopolymers, are disclosed in the patent literature. Reference is made to U.S. Pat. Nos. 4,054,553, 4,092,294, 4,477,649, 4,477,651 and 4,517,341, the disclosures of which are incorporated by reference herein.

In one embodiment, the PPO polymer is poly(2,6-dimethylphenylene oxide), which is available under the trade name PPO™ from SABIC Innovative Plastics, Pittsfield, Mass.

The polymer used to make the trays of the present invention may be a blend of a PPE polymer, as described above, with one or more additional polymers. Suitable polymers which may be used in the PPE polymer compositions include styrenics, such as polystyrene (PS), acrylonitrile butadiene styrene (ABS), styrene acrylonitrile (SAN), styrene butadiene rubber (SBR), high impact styrene (HIPS), polyalphamethylstyrene, styrene maleic anhydride (SMA), styrene-butadiene copolymer (SBC) (such as styrene-butadiene-styrene copolymer (SBS) and styrene-ethylene/butadiene-styrene copolymer (SEBS)), styrene-ethylene/propylene-styrene copolymer (SEPS), styrene butadiene latex (SBL), SAN modified with ethylene propylene diene monomer (EPDM) and/or acrylic elastomers (for example, PS-SBR copolymers), or combinations thereof. Other styrenic block copolymers are also included within the scope of the invention.

In one embodiment, the polymer is a blend of a PPE polymer, as described above, and a polystyrene polymer and/or a high impact polystyrene polymer. In one embodiment, the polymer is a blend of a PPE polymer and a styrenic block copolymer. In one embodiment, the polymer is a blend of a PPE polymer and any one or more of the styrenics described above. Useful examples of PPE blends include Noryl™, and Xyron™.

Other useful polymers and polymer blends include: Accuguard™ PPE and Accutech™ PPE, available commercially from ACLO Compounders Inc.; Acnor™ PPE-PS blend, available from Aquafil Technopolymers SpA; any of the Xyron™ line of materials including the PPE-PP, PPE-PS, PPE-PE-Nylon, and PPE-SP-PP blends, available from Asahi Kasei Corporation; Ashlene™ PPE, PPE-PS, and PPE-PS-Nylong blends, available from Ashley Polymers, Inc.; Blendex™ PPE and PPE-PS-Nylong blends, available from Chemutra; Norpex™ PPE available from Custom Resins Group; Delta™ PPE-PS and PPE-PS-Nylon blends available from Delta Polymers; Luranyl™ PPE-PS available from Diamond Polymers, Inc.; EnCom™ PPE-PS available from EnCom, Inc.; Ensinger™ PPE-PS available from Ensinger Inc.; Tekappo™ PPE-PS available from E-Polymers Co. Ltd.; Vestoran™ PPE available from Evonik Degussa AG; Styvex™ PPE-PS available from Ferro Corporation; Jamplast™ PPE-PS available from Jamplast, Inc.; Kern™ PPE-PS available from Kern GmbH; Laril™ PPE-PS and LatioHM PPE-PS available from LATI SpA; Lucon™ PPE and PPE-PS-Nylon blends available from LG Chem Ltd.; Astaryl™ PPE-PS available from Marplex Austrailia Pty. Ltd.; Iupiace™ PPE-PS, PPE-PS-Nylon blends, Lemalloy™ PPE, PPE-Nylon 66, PPE-PP, and PPE-PS-Nylon blends available from Mitsubishi Engineering-Plastics Corp.; DiaAlloy™ PPE available from Mitsubishi Rayon America Inc.; Uninor™ PPE-PS available from Nytef Plastics, Ltd.; OP-PPO PPE-PS available from Oxford Polymers; PRL PPE-PS available from Polymer Resources Ltd.; Ramlloy PPE-PS available from Polyram-On Industries; PRE-ELEC PPE available from Premix Thermoplastics, Inc.; QR Resin PPE-Nylon 66, PPE-PS, and PPE-PS-Nylon available from QTR, Inc.; Quadrant EPP PPE available from Quadrant Engineering Plastic Products; Luranyl™ PPE-Nylon 66 and PPE-PS available from ROMIRA GmbH; RTP Compounds PPE and PPE-PS available from RTP Company; LNP Lubricomp™ PPE-PS, LNP Lubriloy™ PPE-PS, LNP Stat-Kon™ PPE-PS, LNP Stat-Loy™ PPE-PS-Nylon, LNP Thermocomp PPE and PPE-PS, Noryl™ GTX PPE-PS-Nylon, Nory™ PPX PPE-PS-PP, Noryl™ PPE-polyolefin, PPE-PS, PPE-PS-PP, and Prevex™ PPE-PS, and LNP Faradex™ PPE-PS blends all available from one or more of the SABIC Innovative Plastics divisions; Staren™ PPE and PPE-PS available from Samsung; Shuman PPO PPE-PS available from Shuman Plastics, Inc.; Norfor™ PPE-PS available from SO.F.TER SPA; PrimoSpire™ SRP available from Solvary Advanced Polymers; Spartech Polycom PPE and PPE-PS available from Spartech Polycom; Knorstan™ PPE-PS available from Technical Polymers, LLC; Emiclear PPE available from Toshiba Chemical Corporation; HiFill FR™ PPE-PS and Lubriblend™ PPE-PS-Nylon available from TP Composites, Inc.; Tyneloy™ PPE-PS available from Tyne Plastics LLC.; Deloxen™ PPE and Vamporan™ PPE available from Vamp Tech; Norylux™ PPE-PS-Nylon available from Westlake Plastics Company; or any combination thereof.

### The Conductive Filler

The trays of the present invention are made from a thermoplastic polymer composition comprising a PPE polymer component, a conductive filler, an impact modifier, and optionally, one or more additional additives.

The conductive filler component is not overly limited. In some embodiments, the conductive filler comprises carbon black, carbon fiber, carbon nanotubes, graphene, metallic filler, or combinations thereof. Suitable examples of nano-sized conductive fillers are multiwall carbon nanotubes (MWNTs), vapor grown carbon fibers (VGCF), carbon black, graphite, conductive metal particles, conductive metal oxides, metal coated fillers, nano-sized conducting organic/organometallic fillers conductive polymers, and the like, and combinations comprising at least one of the foregoing nano-sized conductive fillers. In one embodiment, these nano-sized conductive fillers may be added to the conductive precursor composition during the polymerization of the polymeric precursor. In another embodiment, the nano-sized conductive fillers are added to the organic polymer and the SWNT composition during manufacturing to form the conductive composition.

In some embodiment, the conductive filler used in the present invention are nano-sized. That is, the conductive filler has at least one dimension less than or equal to about 1,000 nm. The nano-sized conductive fillers may be 1, 2 or 3-dimensional and may exist in the form of powder, drawn wires, strands, fibers; tubes, nanotubes, rods, whiskers, flakes, laminates, platelets, ellipsoids, discs, spheroids, and the like, or combinations comprising at least one of the foregoing forms. They may also have fractional dimensions and may exist in the form of mass or surface fractals.

### The Impact Modifier

The trays of the present invention are made from a thermoplastic polymer composition comprising a PPE polymer component, a conductive filler, an impact modifier, and optionally, one or more additional additives.

The impact modifiers suitable for use in the present invention are not overly limited. In some embodiments, the impact modifier includes a styrenic block copolymer, an ethylene acrylate copolymer, or combinations thereof.

Useful examples of impact modifiers include: block copolymers of styrene and ethyelene/butylene (one example of which is available commercially under the Kraton™ tradename); acrylonitrile butadiene styrene thermoplastics based on polybutadiene rubber (one example of which is available commercially under the Blendex™ tradename from Chemtura); copolymers of ethylene and methyl acrylate (one example of which is available commercially under the Elvaloy™ tradename from DuPont); block copolymers of styrene, ethylene, butylene and styrene (one example of which is available commercially under the Kraton™ tradename); copolymers of ethylene and glycidyl methacrylate (one example of which is available commercially under the Lotader™ tradename from Arkema); copolymers of ethylene, methyl acrylate and glycidyl methacrylate (one example of which is available commercially under the Lotader™ tradename from Arkema); silicone-acrylic based rubbers (one example of which is available commercially under the Metablen™ trade name from Mitsubishi Rayon); or combinations thereof.

In some embodiments, the impact modifier comprises block copolymers of styrene and ethyelene/butylene; acrylonitrile butadiene styrene thermoplastics based on polybutadiene rubber; copolymers of ethylene and glycidyl methacrylate; copolymers of ethylene, methyl acrylate and glycidyl methacrylate; or combinations thereof.

In some embodiments, the impact modifier includes elastomeric or rubbery materials having a Tg equal to or less than 0 degrees C. and in some embodiments equal to or less than −10, −20, or even −30 degrees C. Tg is the temperature or temperature range at which a polymeric material shows an abrupt change in its physical properties, including, for example, mechanical strength. Tg can be determined by differential scanning calorimetry.

Suitable impact modifiers include polymers such as styrene-ethylene-butylene-styrene (SEBS), styrene-butadiene rubber (SBR), polybutadiene (PB), or acrylate rubbers, particularly homopolymers and copolymers of alkyl acrylates having from four to six carbons in the alkyl group. Suitable impact modifiers can also be grafted homopolymers or copolymers of butadiene that are grafted with a polymer of styrene and methyl methacrylate. Some of the preferred rubber-containing materials of this type are the known methyl methacrylate, butadiene, and styrene-type (MBS-type) core/shell grafted copolymers having a Tg equal to or less than 0 degrees C. and a rubber content greater than about 40 percent, typically greater than about 50 percent.

Other impact modifiers useful in the compositions of this invention are those based generally on a long-chain, hydrocarbon backbone, which may be prepared predominantly from various mono- or dialkenyl monomers and may be grafted with one or more styrenic monomers. Representative examples of a few olefinic elastomers which illustrate the variation in the known substances which would suffice for such purpose are as follows: butyl rubber; chlorinated polyethylene rubber; chlorosulfonated polyethylene rubber; an olefin homopolymer such as polyethylene or polypropylene or copolymer such as ethylene/propylene copolymer, ethylene/styrene copolymer or ethylene/propylene/diene copolymer, which may be grafted with one or more styrenic monomers; neoprene rubber; nitrile rubber; polybutadiene and polyisoprene.

In some embodiments, the impact modifier is a polyolefin elastomer comprising one or more C₂₋₂₀ alpha-olefins in polymerized form. Examples of the types of polymers from which the present polyolefin elastomers are selected include copolymers of alpha-olefins, such as ethylene and propylene, ethylene and 1-butene, ethylene and 1-hexene or ethylene and 1-octene copolymers, and terpolymers of ethylene, propylene and a diene comonomer such as hexadiene or ethylidene norbornene.

In some embodiments, the impact modifier is a substantially linear ethylene polymer (SLEP) or a linear ethylene polymer (LEP), or a mixture of one or more of each. Both substantially linear ethylene polymers and linear ethylene polymers (S/LEP) are known. Substantially linear ethylene polymers and their method of preparation are fully described in U.S. Pat. No. 5,272,236 and U.S. Pat. No. 5,278,272. Linear ethylene polymers and their method of preparation are fully disclosed in U.S. Pat. No. 3,645,992; U.S. Pat. No. 4,937,299; U.S. Pat. No. 4,701,432; U.S. Pat. No. 4,937,301; U.S. Pat. No. 4,935,397; U.S. Pat. No. 5,055,438; EP 129,368; EP 260,999; and WO 90/07526.

The impact modifier may be a blend of polymers of a copolymer of monomers that includes one or more polymers and/or monomers that are also present in the polymer component. For example, polystyrene may be present in the polymer component and may also be present in the impact modifier component. In some embodiments, there are no common polymers between the components however there may still be common monomers, that is, polystyrene may be a component of the polymer blend in the polymer component but no polystyrene is present in the impact modifier component. However, a copolymer in the impact modifier component may still contain blocks derived from styrene monomers.

### Additional Additives

The compositions of the present invention may further include additional useful additives, where such additives can be utilized in suitable amounts. These optional additional additives include fillers, reinforcing fillers, pigments, heat stabilizers, UV stabilizers, flame retardants, plasticizers, rheology modifiers, processing aids, lubricants, mold release agents, and combinations thereof. Useful pigments include opacifying pigments such as titanium dioxide, zinc oxide, and titanate yellow. Useful pigments also include tinting pigments such as carbon black, yellow oxides, brown oxides, raw and burnt sienna or umber, chromium oxide green, cadmium pigments, chromium pigments, and other mixed metal oxide and organic pigments. Useful fillers include diatomaceous earth (superfloss) clay, silica, talc, mica, wallostonite, barium sulfate, and calcium carbonate. If desired, useful stabilizers such as antioxidants can be used and include phenolic antioxidants, while useful photostabilizers include organic phosphates, and organotin thiolates (mercaptides). Useful lubricants include metal stearates, paraffin oils and amide waxes. Useful UV stabilizers include 2-(2′-hydroxyphenol)benzotriazoles and 2-hydroxybenzophenones. Additives can also be used to improve the hydrolytic stability of the TPU polymer. Each of these optional additional additives described above may be present in, or excluded from, the compositions described herein.

In some embodiments, the optional additional additives include waxes, release agents, antioxidants, reinforcing fillers, pigments, flame retardants, or combinations thereof. Suitable reinforcing fillers include mineral fillers and glass fibers.

In some embodiments, the compositions of the present invention are substantially free to free of fluorine atoms, chlorine atoms, bromine atoms, iodine atoms, astatine atoms, or combinations thereof (including ions of said atoms). In some embodiments, the compositions of the present invention are substantially free to free of salts and/or other compounds containing fluorine, chlorine, bromine, iodine, and/or astatine atoms, and/or ions of one or more thereof. In some embodiments, the compositions of the present invention are substantially free to free of all halogens atoms, halogen-containing salts, and/or other halogen-containing compounds. By substantially free, it is meant that the compositions contain less than 10,000 parts per million or even 10,000 parts per billion of fluorine/fluoride, chorine/chloride, bromine/bromide, iodine/iodide, astatine/astatide, or combinations of the atoms/ions thereof.

It is known that some of the materials described above may interact in the final formulation, so that the components of the final formulation may be different from those that are initially added. The products formed thereby, including the products formed upon employing the composition of the present invention in its intended use, may not be susceptible of easy description. Nevertheless, all such modifications and reaction products are included within the scope of the present invention; the present invention encompasses the composition prepared by admixing the components described above.

### EXAMPLES

The invention will be further illustrated by the following examples, which sets forth particularly advantageous embodiments. While the examples are provided to illustrate the present invention, they are not intended to limit it.

### Example Set 1

A set of polymers are prepared and tested. These examples are representative of the polymer component of the thermoplastic composition used in the preparation of the trays described here.

Example 1-1 contains a commercially PPE-PS plastic, a ethylene methyl acrylate copolymer impact modifier and carbon black, in a weight ratio of about 5:1:1. The Example also contains a release agent and an antioxidant. Example 1-2 contains another commercially available PPE-PS plastic, a mixture of ethylene methyl acrylate copolymer and linear styrene and ethylene/butylene tri-block copolymer as the impact modifier, and carbon black, in a weight ratio of about 4.5:1:1. The impact modifier in Example 1-2 is a 2:1 mixture, on a weight basis, of the ethylene methyl acrylate copolymer and the linear styrene and ethylene/butylene tri-block copolymer. Both examples contain the same amount of release agent and antioxidant.

Each material is tested to evaluate their physical properties. The results of this testing is presented in the table below.

TABLE 1
Properties of Example Set 1.

| Physical Property | Example 1-1 | Example 1-2 |
|---|---|---|
| Melt Flow Index, 300 C./5 kg (g/10 min)¹ | 4.6 | 3.0 |
| Tensile Stress at Yield (psi)² | 4091 | 4725 |
| Tensile Strain at Yield (%)² | 2.2 | 2.25 |
| Tensile Stress at Break (psi)² | 5791 | 6812 |
| Tensile Strain at Break (%)² | 16.5 | 13.2 |
| Tensile Modulus (kpsi)² | 254 | 285 |
| Flexural Modulus (kpsi)³ | 333 | 383 |
| Notched IZOD Impact (ft-lb/in)⁴ | 2.6 | 3.1 |
| Heat Distortion Temp at 66 psi | 171 | 156 |
| (degrees C.)⁵ | | |
| Heat Distortion Temp at 264 psi | 149 | 136 |
| (degrees C.)⁵ | | |
| Sheet Surface Resistivity (ohms)⁶ | <1E+04 | 1E+05 |

¹Melt Flow Index (MFI) is measured according to ASTM D1238.
²All Tensile testing is measured according to ASTM D638.
³Flexural Modulus is measured according to ASTM D790-95 at 0.05 in/min.
⁴Notched IZOD Impact is measured according to ASTM D256-93a.
⁵All Heat Distortion testing is measured according to ASTM D648.
⁶Sheet Surface Resistivity is measured according to ESD S11.11 at 12% relative humidity.

### Example Set 2

A set of polymers are prepared and tested. These examples are representative of the polymer component and conductive filler of the thermoplastic composition used in the preparation of the trays described here.

Example 2-1 and Example 2-2 are identical expect for the polymer component used. Each example contains a commercially available copolymer of ethylene and glycidyl methacrylate as the impact modifier, carbon black, a release agent and an antioxidant in the same amounts and proportions. Example 2-1 uses the commercially available PPE-PS used in Example 1-2 while Example 2-2 uses the commercially available PPE-PS used in Example 1-1. Both examples are mixed at a 100:27.6 weight ratio of polymer component to conductive filler. Each material is tested to evaluate their physical properties. The results of this testing is presented in the table below.

TABLE 2
Properties of Thermoplastic Composition without Impact Modifier

| Physical Property | Example 2-1 | Example 2-2 |
|---|---|---|
| Tensile Stress at Yield (psi)¹ | 7120 | 5750 |
| Tensile Strain at Yield (%)¹ | 5.75 | 5.01 |
| Tensile Stress at Break (psi)¹ | 6960 | 5670 |
| Tensile Strain at Break (%)¹ | 6.85 | 4.63 |
| Tensile Modulus (kpsi)¹ | 315 | 273 |
| Flexural Modulus (kpsi)² | 279 | 232 |
| Notched IZOD Impact (ft-lb/in)³ | 3.38 | 3.62 |
| Heat Distortion Temp at 66 psi (degrees C.)⁴ | 149 | 161 |
| Specific Gravity | 1.116 | 1.117 |
| Sheet Surface Resistivity (ohms)⁵ | 1.8E+05 | 7.8E+04 |
| Volume Resistivity (ohm-cm)⁵ | 4.0E+06 | 2.2E+05 |
| Static Decay Rate at 1000 V-10 V (s)⁵ | 0.0 | 0.0 |

¹All Tensile testing is measured according to ASTM D638.
²Flexural Modulus is measured according to ASTM D790-95 at 0.05 in/min.
³Notched IZOD Impact is measuted according to ASTM D256-93a.
⁴All Heat Distortion testing is measured according to ASTM D648.
⁵Sheet Surface Resistivity is measured according to ESD S11.11 at 12% relative humidity. Volume Resistivity is measured according to ESD S11.12 at 12% relative humidity. The Static Decay Rate is measured according to CPM at 50% relative humidity.

### Examples Set 3

A set of polymers are prepared and tested. These examples are representative of the thermoplastic composition used in the preparation of the trays described here. These compositions contain a polymer component, a conductive filler component, and an impact modifier component.

Each example is Example Set 3, except for the comparative example 3-8, uses the same basic formula. Examples 3-1 to 3-7 are identical except that each example in the set has a different impact modifier present. Each example in the set contains the commercially available PPE-PS plastic used in Example 1-2 as an impact modifier, and carbon black as the conductive filler in weight ratios of about 7:1:2. Each example also contains the same release agent and antioxidant in the same amount.

Example 3-1 includes a commercially available block copolymer of styrene and ethylene/butylene. Example 3-2 includes a commercially available acrylonitrile butadiene styrene thermoplastic based on polybutadiene rubber. Example 3-3 includes a commercially available copolymer of ethylene and methyl acrylate. Example 3-4 includes a commercially available block copolymer of styrene, ethylene, butylene and styrene. Example 3-5 includes a commercially available copolymer of ethylene and glycidyl methacrylate. Example 3-6 includes commercially available copolymers of ethylene, methyl acrylate and glycidyl methacrylate different from that used in Example Set 2. Example 3-7 includes commercially available silicone-acrylic based rubbers. Each material is tested to evaluate their physical properties. The results of this testing is presented in the table below.

Comparative Example 3-8 contains the same polymer component and conductive filler as the other examples in the set but no impact modifier, release agent or antioxidant. The amount of conductive filler is the same as the other examples in the table, with the amount of polymer increased to cover the missing components.

TABLE 3
Properties of Thermoplastic Composition

| | Ex | Ex | Ex | Ex | Ex | Ex | Ex | Ex |
|---|---|---|---|---|---|---|---|---|
| Physical Property | 3-1 | 3-2 | 3-3 | 3-4 | 3-5 | 3-6 | 3-7 | 3-8 |
| Tensile Stress at Yield (kpsi)¹ | 16.2 | 6.6 | 5.7 | 5.4 | 5.1 | 6.2 | 6.2 | 7.8 |
| Tensile Strain at Yield (%)¹ | 2.4 | 2.2 | 2.2 | 2.2 | 2.2 | 2.9 | 2.9 | 2.3 |
| Tensile Stress at Break (kpsi)¹ | 18.5 | 7.6 | 9.3 | 7.7 | 8.1 | 7.6 | 7.6 | 9.9 |
| Tensile Strain at Break (%)¹ | 9.0 | 2.6 | 4.5 | 3.9 | 10.4 | 12.2 | 12.2 | 3.0 |
| Tensile Modulus (kpsi)¹ | 357 | 415 | 354 | 334 | 313 | 258 | 258 | 461 |
| Flexural Strength (kpsi)² | 15.3 | 12.8 | 15.2 | 15.2 | 13.9 | 13.6 | 13.6 | 10.9 |
| Flexural Modulus (kpsi)² | 448 | 526 | 450 | 450 | 404 | 390 | 390 | 596 |
| Notched IZOD Impact (ft-lb/in)³ | 1.04 | 0.64 | 0.83 | 0.83 | 2.30 | 2.36 | 2.36 | Low⁵ |
| Surface Resistivity (ohms)⁴ | 6.7 | 2.8 | 6.4 | 2.2 | 7.9 | 3.3 | 4.6 | 1.2 |
| | E+04 | E+04 | E+05 | E+06 | E+03 | E+04 | E+07 | E+05 |

¹All Tensile testing is measured according to ASTM D638.
²Flexural testing is measured according to ASTM D790-95 at 0.05 in/min.
³Notched IZOD Impact is measured according to ASTM D256-93a.
⁴Sheet Surface Resistivity is measured according to ESD S11.11 and ESD S11.12 at 12% relative humidity.
⁵Notched IZOD Modulus for Example 3-8 was too low to measure.

The results show that the compositions of the present invention, and so the trays made from such compositions, have good physical properties making them particularly suitable as IC component trays which may be used through multiple steps of the manufacturing process, including one or more of the steps of sorting, transferring, shipping, sorting, and baking. In particular, the results show the compositions of the present invention can provide an advantageous balance of resistivity, impact and flexural strength, without compromising tensile strength. In some embodiments, the compositions of the present invention provide improved electrical properties in the form of reduced resistance compared to the non-impact-modifier containing baseline.

Each of the documents referred to above is incorporated herein by reference. Except in the Examples, or where otherwise explicitly indicated, all numerical quantities in this description specifying amounts of materials, reaction conditions, molecular weights, number of carbon atoms, and the like, are to be understood as modified by the word “about.” Unless otherwise indicated, all percent values, ppm values and parts values are on a weight basis. Unless otherwise indicated, each chemical or composition referred to herein should be interpreted as being a commercial grade material which may contain the isomers, by-products, derivatives, and other such materials which are normally understood to be present in the commercial grade. However, the amount of each chemical component is presented exclusive of any solvent or diluent oil, which may be customarily present in the commercial material, unless otherwise indicated. It is to be understood that the upper and lower amount, range, and ratio limits set forth herein may be independently combined. Similarly, the ranges and amounts for each element of the invention can be used together with ranges or amounts for any of the other elements. As used herein, and unless otherwise defined, the expression “substantially free of” may mean that and amount that does not materially affect the basic and novel characteristics of the composition under consideration, in some embodiments it may also mean no more than 5%, 4%, 2%, 1%, 0.5% or even 0.1% by weight of the material is questions is present, in still other embodiments it may mean that less than 1,000 ppm, 500 ppm or even 100 ppm of the material in question is present. As used herein, the expression “consisting essentially of” permits the inclusion of substances that do not materially affect the basic and novel characteristics of the composition under consideration.

1. A thermoformed tray for transporting and processing integrated circuit (IC) chips comprising at least one pocket designed to receive said IC chips, wherein said tray comprises a thermoplastic polymer compound comprising:
(i) a poly(phenylene ether) polymer;
(ii) a conductive filler;
(iii) an impact modifier; and
(iv) optionally one or more additional additives.

2. The tray of claim 1 wherein said polymer is selected from the group consisting of poly(phenylene ether) homopolymer, poly(phenylene ether) copolymer, poly(phenylene ether) homopolymer and/or copolymer blend, or combinations thereof;
wherein said poly(phenylene ether) homopolymer and/or copolymer blend comprises a poly(phenylene ether) homopolymer and/or copolymer blended with an additional component comprising polystyrene, high impact polystyrene, styrenic block copolymers, acrylonitrile butadiene styrene polymer, styrene acrylonitrile polymer, or combinations thereof.

3. The tray of claim 1 wherein said poly(phenylene ether) polymer comprises poly(2,6-dimethylphenylene oxide) polymer

4. The tray of claim 1 wherein said thermoplastic polymer compound has a heat distortion temperature of no lower than 130 degrees C. as measured under 66 psi (0.46 MPa) according to ASTM D-648.

5. The tray of claim 1 wherein said impact modifier comprises a styrenic block copolymer, an ethylene acrylate copolymer, or combinations thereof.

6. The tray of claim 1 wherein said impact modifier is present in the overall composition from 1 to 30 percent by weight.

7. The tray of claim 1 wherein said conductive filler comprises carbon black, carbon fiber, carbon nanotube, graphene, metallic filler, or combinations thereof.

8. The tray of claim 1 wherein said thermoplastic polymer compound has a surface resistance of less than 1E8 ohm as measured according to ESD S11.11.

9. The tray of claim 1 wherein the optional additional additive component comprises waxes, antioxidants, reinforcing fillers, pigments, flame retardants, or combinations thereof.

10. The tray of claim 1 wherein said thermoplastic polymer compound has a flexural modulus of at least 250 kpsi (1724 MPa) as measured according to ASTM D-790.

11. The tray of claim 1 wherein said thermoplastic polymer compound has a specific gravity of less than 1.18 g/cc as measured according to ASTM D-792.

12. The tray of claim 1 wherein:
(i) said thermoplastic polymer compound has a heat distortion temperature of no lower than 130 degrees C. as measured under 66 psi according to ASTM D-648;
(ii) said thermoplastic polymer compound has a surface resistance of less than 1E8 ohms as measured according to ESD S11.11;
(iii) said thermoplastic polymer compound has a flexural modulus of at least 250 kpsi (1724 MPa) as measured according to ASTM D-790;
(iv)said thermoplastic polymer compound has a specific gravity of less than 1.18 g/cc as measured according to ASTM D-792; or
(v) any combination thereof.

13. The tray of claim 1 wherein said thermoplastic polymer compound is:
(i) 50 to 99 percent by weight of one or more poly(phenylene ether) polymers;
(ii) 1 to 25 percent by weight of one or more conductive fillers;
(iii) 1 to 25 percent by weight of one or more impact modifiers; and
(iv) 0 to 30 percent by weight of one or more optional additional additives;
wherein all weight percent values are with regards to the overall thermoplastic polymer compound.

14. The tray of claim 1 wherein said tray is produced by the thermoforming of a sheet of said thermoplastic polymer compound.
